(19) United States
(12) Patent Application Publication
(10) Pub. No.: US 2006/0006474 A1
(43) Pub. Date: Jan. 12, 2006

(54) Semiconductor device

(76) Inventor: Nobuo Tsuboi, Hyogo (JP)

Correspondence Address: MCDERMOTT WILL & EMERY LLP, 600 13TH STREET, N.W., WASHINGTON, DC, 20005-3096, US

(21) Appl. No.: 11/178,606

(22) Filed: Jul. 12, 2005

(30) Foreign Application Priority Data
Jul. 12, 2004 (JP) JP 2004-204884 (P
Jun. 20, 2005 (JP) JP 2005-179192 (P

(51) Int. Cl. H01L 29/76

(52) U.S. Cl. 257/369

(57) ABSTRACT

In an active region a pair of source/drain regions of an nMOS transistor is provided. Between the paired source/drain regions the semiconductor substrate has a region provided with a gate electrode layer with a gate oxide film interposed. The gate electrode layer extends on both the active region and an element isolation structure and also has a contact pad portion on the element isolation structure, and the active region and the contact pad as seen in a plane are spaced by less than 0.5 μm.

### BACKGROUND OF THE INVENTION

1. Field of the Invention

The present invention relates generally to semiconductor devices and particularly to semiconductor devices having a metal insulator semiconductor (MIS) transistor.

2. Description of the Background Art

When a minimally dimensioned complementary metal oxide semiconductor (CMOS) circuit is configured, its device is designed in accordance with a design rule defined for each generation. For example, for a transistor, a gate's pitch space, an active region's area and the like are determined in accordance with the design rule. Generally, this design rule is common between n channel MOS (nMOS) and p channel MOS (pMOS) transistors.

Such a transistor has a gate electrode laid out as shown for example in Japanese Patent Laying-Open No. 09-129744.

Conventionally a gate electrode has a contact pad portion having a structure larger in width than a gate portion to prevent a contact from stepping out a shallow trench isolation (STI) region. On the other hand, for a further microfabricated device, laying out and arranging in accordance with a design value rounds off a pattern of a right angle because of optical proximity effect, resulting in a rounded corner, provides a shortened line pattern, tapered and expanded patterns, and similar pattern density dependency.

When corner rounding is caused at a portion connecting the contact pad portion of the gate electrode and the gate portion on the active region, the gate portion's stroke width increases in a vicinity thereof. This affects a transistor's source-drain current Ids and other electrical characteristics. Accordingly, optical proximity correction is applied to a photomask to introduce a correction to finish in accordance with a design value. However, between the contact pad portion and the active region a prescribed spacing must be ensured to minimize effect on the transistor's electrical characteristics. As such, it has been difficult to provide conventional semiconductor devices with high degrees of integration.

### SUMMARY OF THE INVENTION

The present invention contemplates a semiconductor device that can help to provide increased degree of integration.

The present invention in one aspect provides a semiconductor device having an nMIS transistor and a pMIS transistor, including: a semiconductor substrate; an element isolation structure provided at a main surface of the semiconductor substrate to electrically isolate active regions of the semiconductor substrate; source and drain regions of the nMIS transistor provided at the active region; and a gate electrode layer of the nMIS transistor provided on a region of the semiconductor substrate sandwiched between the source and drain regions, with an insulation layer posed therebetween, wherein the gate electrode layer extends on both the active region and the element isolation structure and also has a wider portion on the element isolation structure, and the active region and the wider portion as seen in a plane are spaced by less than 0.5 μm.

In the present specification a “wider portion” typically refers to a contact pad portion, a bent portion or a similar portion in a gate electrode layer that is larger in width than a portion located on an active region and having a minimal width (or a minimal width in a direction of a gate length). Note that if it gradually or stepwise varies in width, a portion of the gate electrode layer located in a vicinity of the active region and having a maximum width will be referred to as a “wider portion”.

The present invention in another aspect provides a semiconductor device having an nMIS transistor and a pMIS transistor, including: a semiconductor substrate; an element isolation structure provided at a main surface of the semiconductor substrate to electrically isolate first and second active regions of the semiconductor substrate; source and drain regions of the nMIS transistor provided at the first active region; and a gate electrode layer of the nMIS transistor provided on a region of the semiconductor substrate sandwiched between the source and drain regions of the nMIS transistor, with a first insulation layer posed therebetween; source and drain regions of the pMIS transistor provided at the second active region; and a gate electrode layer of the pMIS transistor provided on a region of the semiconductor substrate sandwiched between the source and drain regions of the pMIS transistor, with a second insulation layer posed therebetween, wherein: the gate electrode layer of the nMIS transistor extends on both the first active region and the element isolation structure and also has a first wider portion on the element isolation structure; the gate electrode layer of the pMIS transistor extends on both the second active region and the element isolation structure and also has a second wider portion on the element isolation structure; and as seen in a plane, the first active region and the first wider portion are spaced by a distance smaller than the second active region and the second wider portion are spaced.

The present invention in still another aspect provides a semiconductor device including: a semiconductor substrate; an element isolation structure provided at a main surface of the semiconductor substrate to electrically isolate active regions of the semiconductor substrate; source and drain regions of a MIS transistor provided at the active region; a gate electrode layer of the MIS transistor provided on a region of the semiconductor substrate sandwiched between the source and drain regions, with an insulation layer posed therebetween; and a conductive layer located on the gate electrode layer and connected to the gate electrode layer at least an upper surface, wherein the gate electrode layer as seen along its entire length has a fixed width.

The present invention in one aspect provides a semiconductor device having nMIS and pMIS transistors such that the nMIS transistor has an active region and a wider portion spaced, as seen in a plane, by less than 0.5 μm to allow the nMIS transistor to have a higher degree of integration. Note that in the nMIS transistor a rounded corner has a smaller effect on electrical characteristics than in the pMIS transistor and if the spacing is less than 0.5 μm, in the nMIS transistor the rounded corner only minimally affects the electrical characteristics.

The present invention in another aspect can provide a semiconductor device such that an nMIS transistor's first active region and first wider portion, as seen in a plane, are spaced by a distance smaller than a pMIS transistor's second active region and second wider portion are spaced. In the nMIS transistor a rounded corner has a smaller effect on electrical characteristics than in the pMIS transistor and if the spacing is reduced (less than 0.5 μm for example), in the nMIS transistor the rounded corner only minimally affects the electrical characteristics. Thus the electrical characteristics can only be minimally affected while the nMIS transistor can have a higher degree of integration.

The present invention in still another aspect can provide a semiconductor device with a gate electrode layer having, as seen along its entire length, a substantially constant width and free of a portion wide in width. As such, it will not have electrical characteristics affected by a rounded corner. Furthermore, the absence of the portion wide in width can also advantageously contribute to providing a device with a high degree of integration.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view schematically showing a configuration of a semiconductor device in a first embodiment of the present invention.

FIG. 2A is a schematic cross section taken along a line IIa-IIa of FIG. 1, and FIG. 2B is a schematic cross section taken along a line IIb-IIb of FIG. 1.

FIG. 3 is a schematic cross section taken along a line III-III of FIG. 1 showing a contact pad portion with a conductive layer connected thereto.

FIG. 4 is a schematic cross section taken along a line IV-IV of FIG. 1 showing a contact pad portion with a conductive layer connected thereto.

FIG. 5 is a schematic plan view of a gate electrode layer in a different pattern.

FIG. 6 is a plan view of a gate electrode layer with a rounded corner, as observed with a SEM.

FIGS. 7A and 7B are each a plan view of a layout for inspecting an effect of corner rounding on electrical characteristic, FIG. 7A showing a layout prone to corner rounding, FIG. 7B showing a layout less prone to corner rounding.

FIG. 8 represents a W1 (a gate portion's stroke width) dependency of a current ratio Ids (pattern A)/Ids (pattern B) in an nMOS transistor.

FIG. 9 represents a W1 (a gate portion's stroke width) dependency of a current ratio Ids (pattern A)/Ids (pattern B) in a pMOS transistor.

FIG. 10 is a schematic cross section showing a different pattern of the gate electrode in the first embodiment.

FIG. 11 is a plan view schematically showing a configuration of the present semiconductor device in a second embodiment.

FIG. 12 is a schematic cross section taken along a line XII-XII of FIG. 11.

FIG. 13 is a schematic cross section showing an overlying line's contact offset from a gate electrode toward a sidewall.

FIG. 14 is a schematic plan view showing one example of a semiconductor device including a pattern having a contact pad portion.

FIG. 15A is a partially enlarged view of FIG. 14 and FIG. 15B shows the FIG. 15A pattern's actual geometry by way of example.

FIG. 16 is a schematic plan view showing one example of a semiconductor device including a pattern which does not have a contact pad portion.

FIG. 17A is a partially enlarged view of FIG. 16 and FIG. 17B shows the FIG. 17A pattern's actual geometry by way of example.

### DESCRIPTION OF THE PREFERRED EMBODIMENTS

Hereinafter the present invention in embodiments will now be described with reference to the drawings.

### First Embodiment

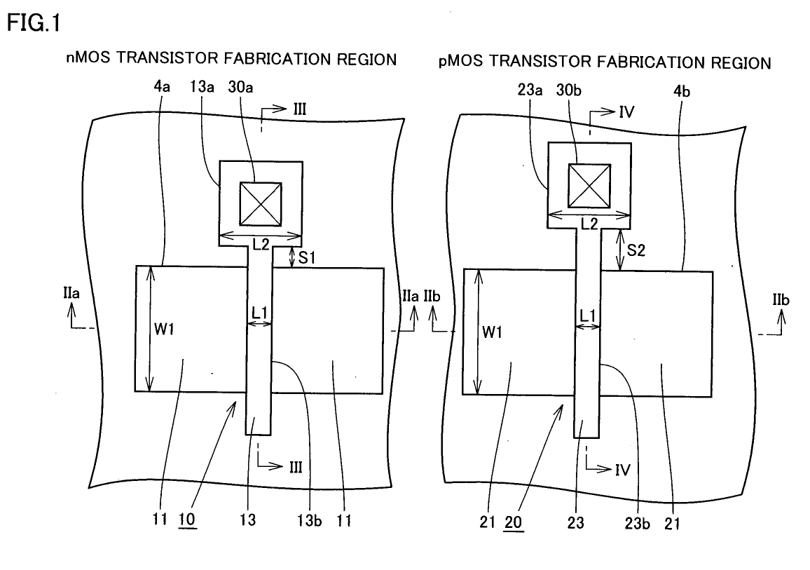

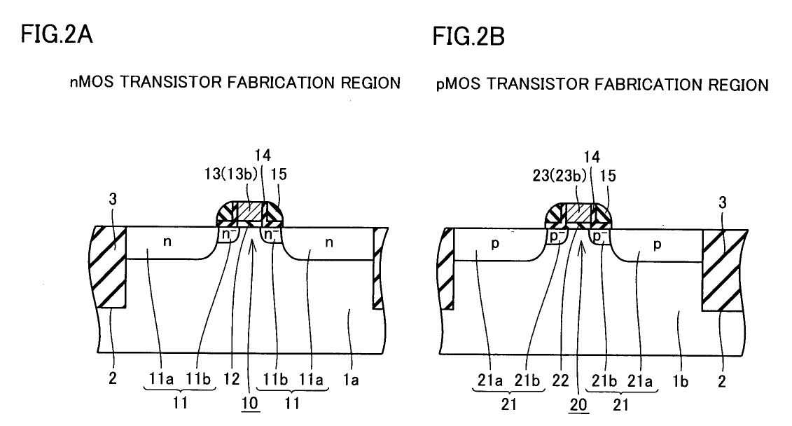

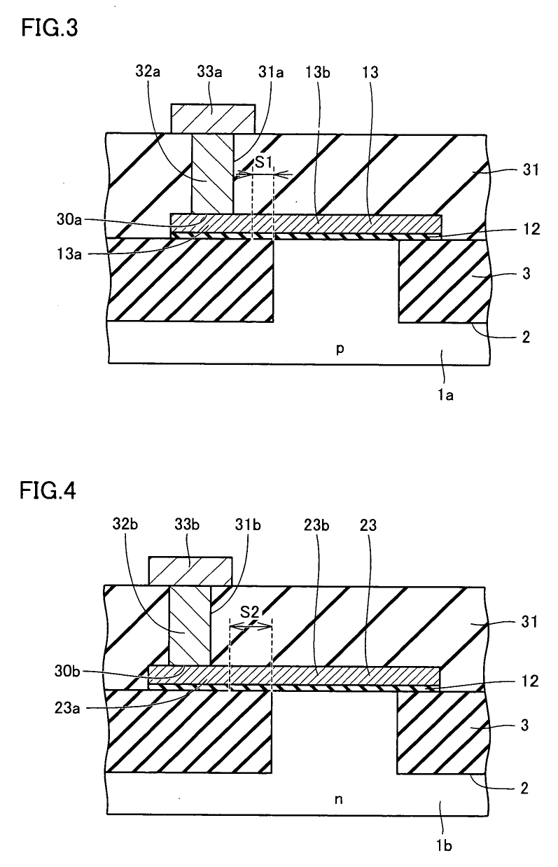

FIG. 1 is a plan view schematically showing a configuration of the present semiconductor device in a first embodiment. FIG. 2A is a schematic cross section taken along a line IIa-IIa of FIG. 1, and FIG. 2B is a schematic cross section taken along a line IIb-IIb of FIG. 1. FIG. 3 is a schematic cross section taken along a line III-III of FIG. 1. FIG. 4 is a schematic cross section taken along a line IV-IV of FIG. 1. Note that FIGS. 3 and 4 show a contact pad portion with a conductive layer connected thereto.

With reference to FIGS. 1 and 2A, in an nMOS transistor fabrication region a semiconductor substrate has a p well 1a having a surface selectively provided with an element isolation structure having a trench isolation structure for example including a trench 2 formed in a surface of the semiconductor substrate and an insulation layer 3 buried in trench 2. This element isolation structure surrounds an active region 4a, as seen in a plane, and thus electrically isolates the active region from other active region. In other words, the element isolation structure serves to electrically isolate active regions from each other.

Active region 4a is provided with an nMOS transistor 10 having a pair of n type source/drain regions 11, a gate oxide film 12 and a gate electrode layer 13. The pair of source/drain regions 11 is provided in a surface of p well 1a such that the source/drain regions are mutually spaced. Paired source/drain regions 11 each have a lightly doped drain (LDD) structure formed for example of a heavily doped n type region 11a and a lightly doped n type region 11b. Between the paired n type source/drain regions 11 the semiconductor substrate underlies gate electrode layer 13 with a gate portion 13b extending on the substrate with gate oxide film 12 interposed.

Gate electrode layer 13 has a sidewall covered with a sidewall insulation layer for example having a 2-layer structure composed of an insulation layer 14 adjacent to the gate electrode layer 13 sidewall and the semiconductor substrate's surface and an insulation layer 15 overlying insulation layer 14. Insulation layer 14 is formed for example of tetra etyle ortho silicate (TEOS) and insulation layer 15 is formed for example of silicon nitride film.

With reference to FIG. 1, gate electrode layer 13 extends on both active region 4a and the element isolation structure and has gate portion 13b extending on active region 4a, and a contact pad portion (or a wider portion) 13a located on the element isolation structure. Contact pad portion 13a has a width (L2) larger than a width of gate portion 13b and, as seen in its width's direction, has a planar geometry projecting with respect to gate portion 13b in opposite directions (in the figure, rightward and leftward). Contact pad portion 13a is a portion electrically connecting an overlying line to gate electrode 13, and the connection portion thereof is a contact 30a.

With reference to FIG. 3, gate electrode layer 13 is covered with an interlayer insulation film 31, which is provided with a hole 31a reaching the contact pad portion 13a of gate electrode layer 13. In hole 31a is provided a conductive layer 32a, which is connected to contact pad portion 13a by contact 30a. Through conductive layer 32a an overlying interconnection layer 33a is electrically connected to gate electrode layer 13.

With reference to FIGS. 1 and 2B, in an pMOS transistor fabrication region a semiconductor substrate has an n well 1b having a surface selectively provided with an element isolation structure having, similarly as has been described above, a trench isolation structure for example including a trench 2 formed in a surface of the semiconductor substrate and an insulation layer 3 buried in trench 2. This element isolation structure surrounds an active region 4b, as seen in a plane, and thus electrically isolates the active region from other active region. In other words, the element isolation structure serves to electrically isolate active regions from each other.

Active region 4b is provided with a pMOS transistor 20 having a pair of p type source/drain regions 21, a gate oxide film 22 and a gate electrode layer 23. The pair of source/drain regions 21 is provided in a surface of n well 1b such that the source/drain regions are mutually spaced. Paired source/drain regions 21 each have a lightly doped drain (LDD) structure formed for example of a heavily doped p type region 21a and a lightly doped p type region 21b. Between the paired p type source/drain regions 21 the semiconductor substrate underlies gate electrode layer 23 with a gate portion 23b extending on the substrate with gate oxide film 22 interposed.

Gate electrode layer 23 has a sidewall covered with a sidewall insulation layer for example having a 2-layer structure composed of an insulation layer 14 adjacent to the gate electrode layer 23 sidewall and the semiconductor substrate's surface and an insulation layer 15 overlying insulation layer 14. Insulation layer 14 is formed for example of tetra etyle ortho silicate (TEOS) and insulation layer 15 is formed for example of silicon nitride film.

With reference to FIG. 1, gate electrode layer 23 extends on both active region 4b and the element isolation structure and has gate portion 23b extending on active region 4b, and a contact pad portion (or a wider portion) 23 a located on the element isolation structure. Contact pad portion 23 a has a width larger than that of gate portion 23b and, as seen in its width's direction, has a planar geometry projecting with respect to gate portion 23b in opposite directions (in the figure, rightward and leftward). Contact pad portion 23a is a portion electrically connecting an overlying wiring to gate electrode 23, and the connection portion thereof is a contact 30b.

With reference to FIG. 4, gate electrode layer 23 is covered with an interlayer insulation film 31, which is provided with a hole 31b reaching the contact pad portion 23a of gate electrode layer 23. In hole 31b is provided a conductive layer 32b, which is connected to contact pad portion 23a by contact 30b. Through conductive layer 32b an overlying interconnection layer 33b is electrically connected to gate electrode layer 23.

With reference to FIG. 1, in the present embodiment a spacing S1 in the nMOS transistor between contact pad portion (or wider portion) 13a and active region 4a is designed to be smaller than a spacing S2 in the pMOS transistor between contact pad portion (or wider portion) 23a and active region 4b. More specifically, spacing S1 is less than 0.5 μm and spacing S2 is 0.5 μm or larger.

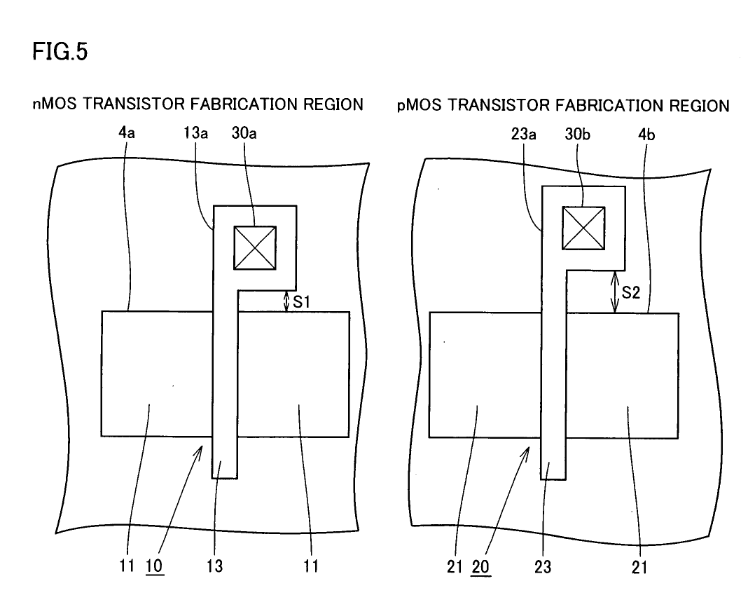

Note that while in the example contact pad portions 13a, 23a project as seen in a direction of a width (i.e., of a gate length L1), with respect to gate portions 13b, 23b in opposite directions, they may have a planar geometry projecting only in one direction, as shown in FIG. 5.

The present inventor has studied to complete the present invention, as described hereinafter.

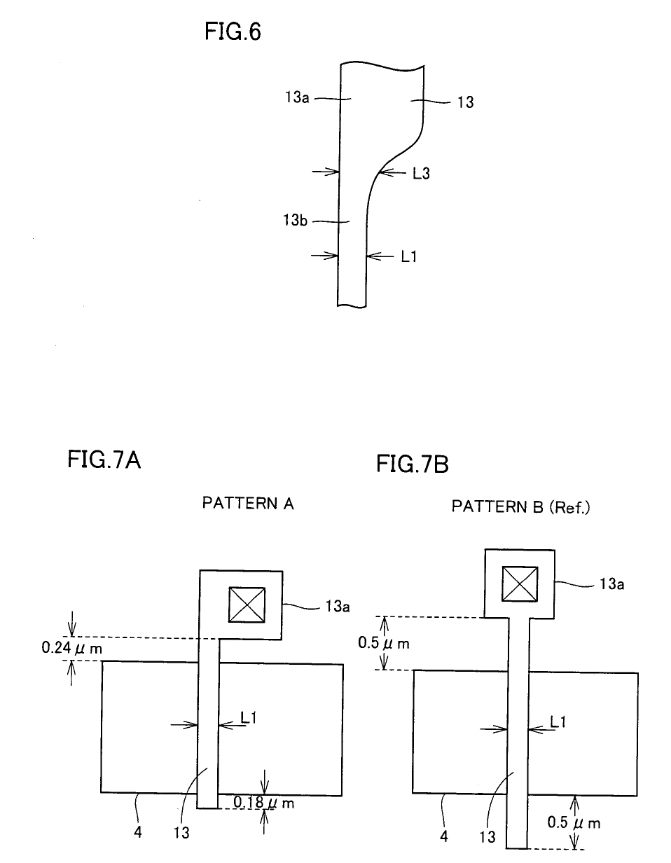

Initially the present inventor employed a scanning electron microscope (SEM) to observe corner rounding in the gate electrode. As a result, as shown in FIG. 6, it was found that gate electrode layer 13 had gate portion 13b and contact pad portion 13a connected via a portion having a rounded corner and contact pad portion 13a also had a rounded corner. Thus in a vicinity of the portion connecting gate portion 13b and contact pad portion 13a gate portion 13b has a gate length L3 larger than a design value and larger than gate length L1 of a different portion of gate portion 13b.

The present inventor then examined how the gate electrode layer 13 rounded corner affects a transistor's electrical characteristics.

FIG. 7A shows a layout (or a pattern A) prone to the gate's corner rounding effect and FIG. 7B shows a layout (or a pattern B) less prone thereto. In the FIG. 7A pattern A gate contact pad portion (or wider portion) 13 a and an active region have therebetween a fixed spacing of less than 0.5 μm (e.g., 0.24 μm) and the gate's free end and the active region have therebetween a fixed spacing of less than 0.5 μm (e.g., 0.18 μm). In the FIG. 7B pattern B gate contact pad portion (or wider portion) 13a and an active region have therebetween a fixed spacing of 0.5 μm and a gate's free end and the active region have therebetween a fixed spacing of 0.5 μm.

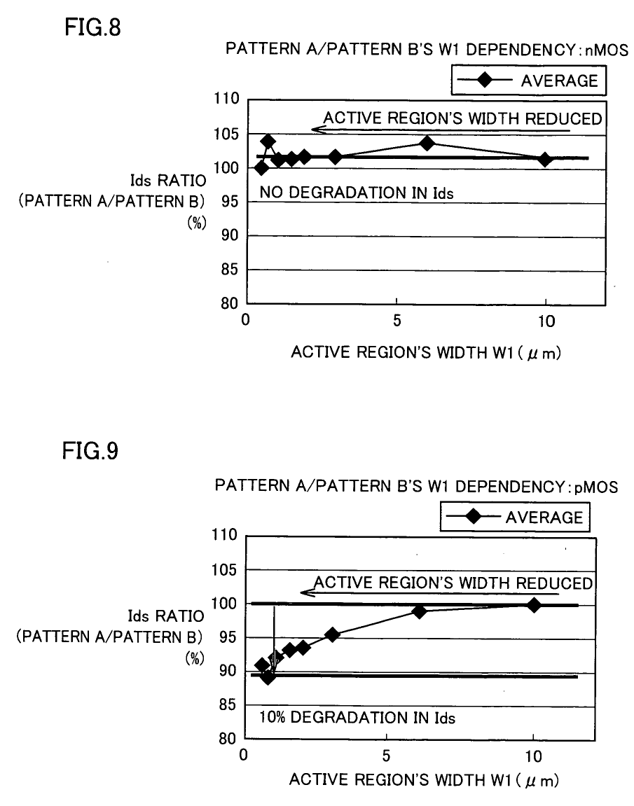

The inventor has examined how the two layouts' respective current ratios Ids (pattern A)/Ids (pattern B) depend on W1 (the active region's width as seen in a direction of a width of the gate, see FIG. 1). FIG. 8 represents how the nMOS transistor's current ratio depends on W1 and FIG. 9 represents how the pMOS transistor's current ratio depends on W1.

FIGS. 8 and 9 show that the nMOS transistor with an active region small in width W1 nonetherless provides less impaired Ids, whereas the pMOS transistor with an active region small in width W1 provides significantly impaired Ids. More specifically, as compared with W1=10 μm, W1=0.5 μm provides an Ids lower by 10%.

As such, if the nMOS transistor is microfabricated in the direction of the active region's width W1, the nMOS transistor is hardly affected by the gate's rounding effect and can thus (1) maintain an ability to drive a current and (2) have the gate's free end and the active region spaced by a reduced distance and the gate compact pad portion or the like's wider portion and the active region spaced by a reduced distance.

In addition to the above effects, the microfabrication in the direction of width W1 can not only provide an increased degree of integration but also a variety of reduced parasitic capacitances and hence faster operation.

Thus even if the nMOS transistor has spacing S1 smaller than spacing S2 of the pMOS transistor, as described in the present embodiment, the n and pMOS transistors are both less susceptible to an electrical characteristic attributed to a rounded corner. Furthermore, such spacing also allows the nMOS transistor to have higher degree of integration.

Furthermore even if spacing S1 is less than 0.5 μm, as described in the present embodiment, the n MOS transistor is less susceptible to an electrical characteristic attributed to a rounded corner. Furthermore, such spacing also allows the nMOS transistor to have higher degree of integration.

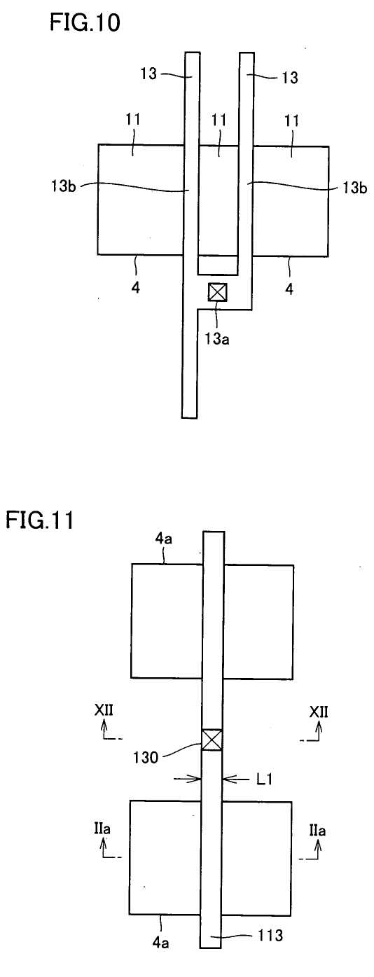

Furthermore, the gate electrode layer's planar pattern is not limited to the FIGS. 1 and 5 patterns and it may be a complicated pattern providing a plurality of gate portions 13b interconnected by a single contact pad portion 13a, as shown in FIG. 10.

Note that the FIG. 10 configuration excluding the above described feature is substantially identical to the FIGS. 1-4 configuration. Accordingly, identical components are identically denoted and will not be described specifically.

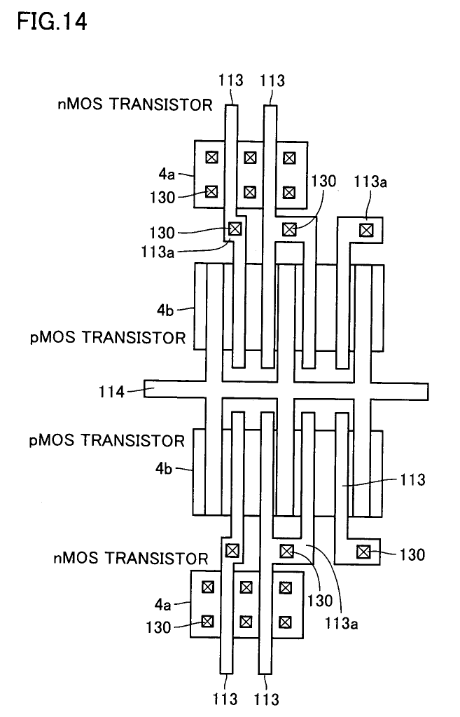

FIG. 14 shows one example of the present semiconductor device with the first embodiment's concept applied thereto. FIG. 14 shows a configuration of a 2-input NOR.

The FIG. 14 semiconductor device has a metal line (a power supply line) 114 at a center as seen in upward and downward directions, and n and pMOS transistors on either side of (or upper and lower than) metal line 114. The n and pMOS transistors are formed on active regions 4a and 4b, respectively, and have a gate electrode layer 113, and source and drain regions. Gate electrode layer 113 on an element isolation structure has a contact pad portion 113a, an example of the wider portion. On active region 4a, 4b at a prescribed location and on contact pad portion 113a, a contact 130 is provided, and active region 4a associated with the nMOS transistor is closer to contact pad portion (or wider portion) 113 than active region 4b associated with the pMOS transistor is.

Note that, as shown in FIG. 14, the n and pMOS transistors are arranged in symmetry with respect to metal line 114, and it is not because a mask used to fabricate the n and pMOS transistors is displaced that active regions 4a and 4b and contact pad portion (or wider portion) 113a are spaced by different distances.

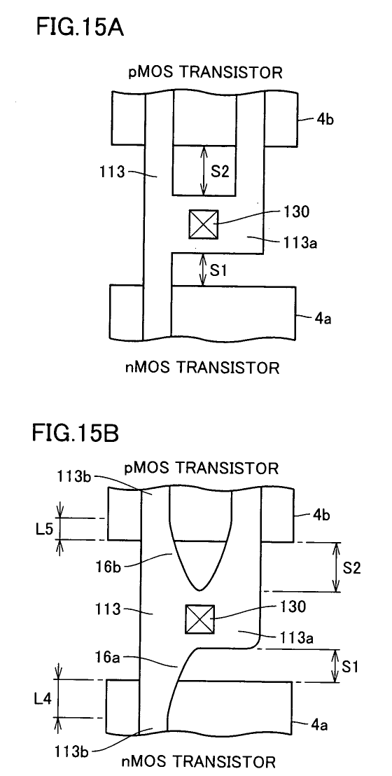

FIG. 15A is an enlarged view of a single contact pad portion 113a in the FIG. 14 semiconductor device and a vicinity thereof.

As shown in FIG. 15A, the nMOS transistor's active region 4a and contact pad portion 113a have spacing S1 therebetween smaller than spacing S2 provided between the pMOS transistor's active region 4b and contact pad portion 113a. Spacing S1 thus reduced can help the MOS transistor to have a higher degree of integration.

FIG. 15B shows the FIG. 15A pattern's actual geometry by way of example. As shown in the figure, gate electrode layer 113 has a portion 16a, 16b located between gate portion 113b and contact pad portion 113a and varying in width. Portion 16a, 16b is formed as a result of corner rounding as described above and in the FIG. 15B example portion 16a, 16b gradually increases in width as it approaches contact pad portion 113a.

Reducing spacing S1 between the nMOS transistor's active region 4a and contact pad portion 113a to be smaller than spacing S2 between the pMOS transistor's active region 4b and contact pad portion 113a results in the nMOS transistor's active region 4a underlying portion 16a having a length L4, and the pMOS transistor's active region 4b underlying portion 16b having a length L5 smaller than L4, as shown in FIG. 15B. As a result, length L4/the active region's width W1 has a value larger than that of length L5/the active region's width W1. Thus in the nMOS transistor if the gate electrode layer's portion varying in width and the active region located immediately thereunder significantly overlap as seen lengthwise the transistor is less impaired in Ids and substantially not impaired in performance.

### Second Embodiment

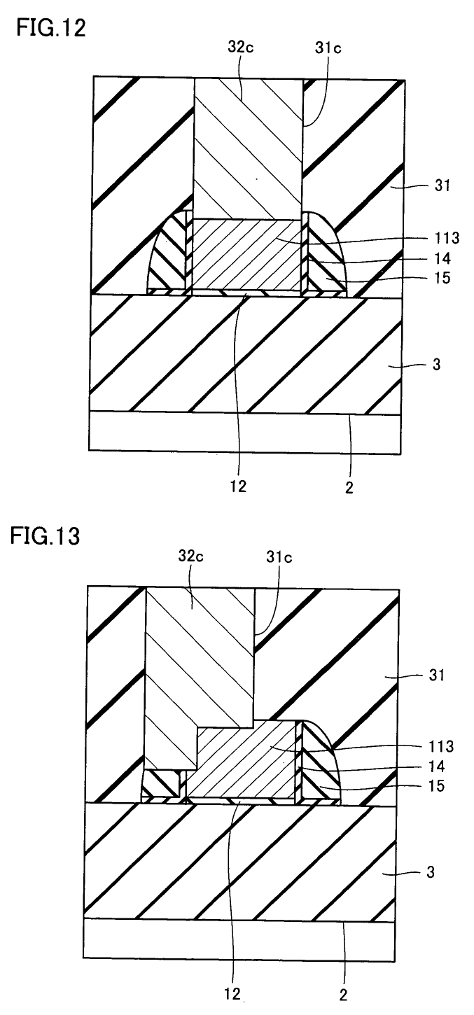

FIG. 11 is a plan view schematically showing a configuration of the present semiconductor device in a second embodiment and FIG. 12 is a schematic cross section taken along a line XII-XII line of FIG. 11. With reference to the figures, in the present embodiment, gate electrode 113 has a uniform width along its entire length. Gate electrode layer 113 is covered with interlayer insulation layer 31 provided with a hole 31c reaching gate electrode layer 113.

In hole 31c is provided a conductive layer 32c for electrically connecting an overlying line to gate electrode layer 113. Conductive layer 32c is connected to gate electrode layer 113 by contact 130. A portion shown in FIG. 11 that is taken along a line IIa-IIa provides a cross section similar in configuration to that shown in FIG. 2A.

Other than the above described feature, the present embodiment provides a configuration substantially similar to that of the first embodiment. Accordingly, identical components are identically denoted and will not be described.

In the present embodiment, in contrast to the first embodiment, gate electrode 113 does not have a contact pad portion, and there is not the effect of rounding attributed to providing a contact pad portion. As such, the pattern in a straight line can prevent impaired Ids attributed to the effect of rounded gate electrode layer 113 and the n and pMOS transistors can both be microfabricated in the direction of the active region's width W1.

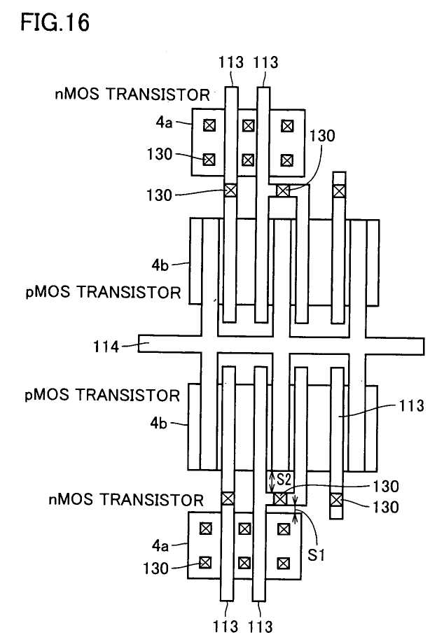

Furthermore, the absence of the contact pad portion allows the present embodiment's pattern (see FIG. 16) without the contact pad portion to be further microfabricated than that with contact pad portion 113a as shown in FIG. 14. Furthermore, in the nMOS transistor fabrication region, microfabrication is allowed in the direction of the active region's width W1 (or the gate's width).

In the present embodiment, however, the contact may step out the gate electrode layer and increased contact resistance may disadvantageously be provided. If conductive layer 32 partly steps out gate electrode layer 113 and are partly offset on a sidewall 14, 15, as shown in FIG. 13, conductive layer 32c contacts gate electrode layer 113 on upper and side walls to ensure that conductive layer 32c contacts gate electrode layer 113 over an area that can be equivalent to that indicated in FIG. 12, and thus reducing an effect on contact resistance.

FIG. 16 shows an example of the present semiconductor device with the present embodiment's concept applied thereto. The FIG. 16 semiconductor device is basically similar in configuration to the FIG. 14 semiconductor device except that the former does not have a contact pad portion.

In the FIG. 16 semiconductor device gate electrode 113 has a bent portion, which corresponds to the wider portion. On this bent portion, contact 130 is provided, and active region 4a associated with fabricating the nMOS transistor is closer to the bent portion than active region 4b associated with fabricating the pMOS transistor. The present example also provides the n and pMOS transistors positionally in symmetry with respect to metal line 114, and it is not because a mask used to fabricate the n and pMOS transistors is displaced that active regions 4a and 4b and the bent portion are spaced by different distances.

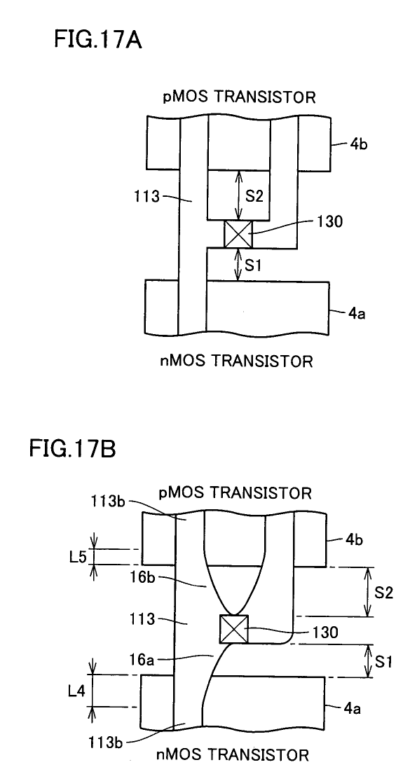

FIG. 17A shows a single bent portion in the semiconductor device shown in FIG. 14, and a vicinity thereof.

As shown in FIG. 1 7A, in the present example, the nMOS transistor's active region 4a and the bent portion has spacing S1 therebetween smaller than spacing S2 provided between the pMOS transistor's active region 4b and the bent portion. Such arrangement, as well as the first embodiment, allows the MOS transistor to have an increased degree of integration. In addition, the FIG. 17A example can dispense with a contact pad portion, and thus provide the MOS transistor with a further increased degree of integration than the first embodiment.

FIG. 17B shows the FIG. 17A pattern's actual geometry by way of example. The FIG. 17B example also provides gate electrode layer 113 having portion 16a, 16b located between gate portion 113b and the bent portion and having a width varying or gradually increasing toward the bent portion.

The FIG. 17B example also provides the nMOS transistor's active region 4a and the bent region with spacing S1 therebetween smaller than spacing S2 provided between the pMOS transistor's active region 4b and the bent portion so that the nMOS transistor's active region 4a underlies portion 16a having length L4 and the pMOS transistor's active region 4b underlies portion 16b having length L5 smaller than L4. As a result, length L4/the active region's width W1 has a value larger than that of length L5/the active region's width W1. In the FIG. 17(B) also, in the nMOS transistor if the gate electrode layer's portion varying in width and the active region located immediately thereunder significantly overlap as seen lengthwise the transistor is less impaired in Ids and substantially not impaired in performance.

While the first and second embodiments have been described for a semiconductor device having a MOS transistor, the present invention is not limited thereto and is applicable to a semiconductor device having an MIS transistor.

Furthermore while the first and second embodiments have been described for a gate electrode layer having a wider portion in the form of a contact pad portion, a bent portion or the like by way of example, the wider portion may be provided in a different form.

Furthermore while the gate electrode layer has a portion having a width gradually increasing toward an element isolation region by way of example, the layer may have a portion having a width gradually reducing toward the region or incrementing/decrementing stepwise toward the region.

The embodiments may also be combined together as appropriate.

The present invention is particularly advantageously applicable to semiconductor devices having a MIS transistor.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having an nMIS transistor and a pMIS transistor, comprising:
a semiconductor substrate;
an element isolation structure provided at a main surface of said semiconductor substrate to electrically isolate active regions of said semiconductor substrate;
source and drain regions of said nMIS transistor provided at said active region; and
a gate electrode layer of said nMIS transistor provided on a region of said semiconductor substrate sandwiched between said source and drain regions, with an insulation layer interposed therebetween, wherein said gate electrode layer extends on both said active region and said element isolation structure and also has a wider portion on said element isolation structure, and said active region and said wider portion as seen in a plane are spaced by less than 0.5 μm.

2. The semiconductor device according to claim 1, wherein said wider portion includes a contact pad portion having a geometry, as seen in a plane, projecting only in one direction with respect to a gate portion of said gate electrode layer.

3. The semiconductor device according to claim 1, wherein said wider portion includes a contact pad portion having a geometry, as seen in a plane, projecting in opposite directions with respect to a gate portion of said gate electrode layer.

4. A semiconductor device having an nMIS transistor and a pMIS transistor, comprising:
a semiconductor substrate;
an element isolation structure provided at a main surface of said semiconductor substrate to electrically isolate first and second active regions of said semiconductor substrate;
source and drain regions of said nMIS transistor provided at said first active region; and
a gate electrode layer of said nMIS transistor provided on a region of said semiconductor substrate sandwiched between said source and drain regions of said nMIS transistor, with a first insulation layer interposed therebetween;
source and drain regions of said pMIS transistor provided at said second active region; and
a gate electrode layer of said pMIS transistor provided on a region of said semiconductor substrate sandwiched between said source and drain regions of said pMIS transistor, with a second insulation layer interposed therebetween, wherein:
said gate electrode layer of said nMIS transistor extends on both said first active region and said element isolation structure and also has a first wider portion on said element isolation structure;
said gate electrode layer of said pMIS transistor extends on both said second active region and said element isolation structure and also has a second wider portion on said element isolation structure; and
as seen in a plane, said first active region and said first wider portion are spaced by a distance smaller than said second active region and said second wider portion are spaced.

5. The semiconductor device according to claim 4, wherein:
said gate electrode layer of said nMIS transistor has a first portion located on said first active region and varying in width;
said gate electrode layer of said pMIS transistor has a second portion located on said second active region and varying in width; and
said first portion is larger in length than said second portion.

6. A semiconductor device comprising:
a semiconductor substrate;
an element isolation structure provided at a main surface of said semiconductor substrate to electrically isolate active regions of said semiconductor substrate;
source and drain regions of a MIS transistor provided at said active region;
a gate electrode layer of said MIS transistor provided on a region of said semiconductor substrate sandwiched between said source and drain regions, with an insulation layer interposed therebetween; and
a conductive layer located on said gate electrode layer and connected to said gate electrode layer at least an upper surface, wherein said gate electrode layer as seen along its entire length has a fixed width.

7. The semiconductor device according to claim 6, further comprising a sidewall insulation layer covering a sidewall of said gate electrode layer.

8. The semiconductor according to claim 7, wherein said conductive layer is located on said gate electrode layer and said sidewall insulation layer and connected to said gate electrode layer at top and side surfaces.
